(19) United States
(12) Patent Application Publication
(10) Pub. No.: US 2026/0090355 A1
(43) Pub. Date: Mar. 26, 2026

(54) INTEGRATED ELECTRONIC DEVICE AND CORRESPONDING PRODUCTION METHOD

(71) Applicant: VALEO COMFORT AND DRIVING ASSISTANCE, Créteil (FR)

(72) Inventors: Raphael Aubry, Créteil (FR); Mourad Azzaz, Créteil (FR)

(73) Assignee: VALEO COMFORT AND DRIVING ASSISTANCE, Créteil (FR)

(21) Appl. No.: 19/109,759

(22) PCT Filed: Aug. 2, 2023
(86) PCT No.: PCT/EP2023/071474

§ 371 Date: Mar. 7, 2025

(30) Foreign Application Priority Data
Sep. 8, 2022 (FR) FR2208975

(51) Int. Cl. H01L 23/482; H01L 23/66; H10D 30/47; H10D 62/85; H10D 84/82

(52) U.S. Cl. CPC H10W 20/40; H10D 30/471; H10D 62/85; H10D 84/82; H10W 44/20; H10W 44/226; H10W 44/251

(57) ABSTRACT

An integrated electronic device includes at least one component produced on a carrier structure including a semiconductor substrate, and an interconnection track (8) that runs over the carrier structure from the component to a lateral face of the device. The interconnection track includes a layer of oxidizable material bearing a continuous layer of conductive material. The layer of oxidizable material is discontinuous. A method for producing such an integrated electronic device is also disclosed herein.

### TECHNICAL FIELD

The present invention relates to the technical field of integrated circuits and in particular integrated circuits comprising one or more components connected to interconnect tracks. The invention is advantageously applicable to the field of integrated circuits which are made from III-V semiconductor materials.

The invention relates in particular to an integrated electronic device and to a method for the production of such a device.

### TECHNOLOGICAL BACKGROUND

In the field of integrated circuits, by way of (non-limiting) example integrated circuits operating at microwave frequencies, or MMIC (Monolithic Microwave Integrated Circuits), it is known practice to protect the components produced on the substrate by encapsulating them in a polymer material.

The input and output signals emitted or received by these components pass through interconnect tracks which extend parallel to the substrate from the components to a lateral face of the integrated circuit (or edge), along component cutting lines, referred to as dicing streets by those skilled in the art. At this point, the interconnect tracks are therefore exposed to the external environment of the component and likely to undergo oxidation due to humidity.

Specifically, it has been found that oxidation that originates at the component cutting line can migrate along the interconnect track, possibly as far as the component. This migration of oxidation is notably promoted by the electric field generated by the signal circulating on the track, and has been particularly observed on the interconnect tracks of transistor drains of the last amplifier stages of MMIC components.

Such oxidation gives rise to delamination of the interconnect track and, if it reaches the component, a modification of the semiconductor surface under the passivation layer at the interface with the interconnect track, thus generating electronic traps which are the cause of a drop in current density in the component. This significantly affects the performance of the component.

### SUMMARY OF THE INVENTION

To overcome the abovementioned drawback, there is proposed a means for preventing the propagation of oxidation along the interconnect track to the active area of the component.

According to one aspect of the invention, there is proposed an integrated electronic device comprising at least one component produced on a carrier structure comprising a semiconductor substrate, and an interconnect track which extends on the carrier structure from the component to a lateral face of the device, the interconnect track comprising a layer of oxidizable material supporting a continuous layer of conductive material, wherein the layer of oxidizable material is discontinuous.

An interconnect track in which the oxidizable part has a discontinuity advantageously makes it possible to stop oxidation on the lateral face propagating toward the component.

According to an embodiment, the device comprises a blocking structure which is interposed between the carrier structure and a portion of the interconnect track, which extends transversely (to the interconnect track) from one edge of the interconnect track to the other and which has an upper face facing away from the carrier structure, the layer of oxidizable material comprising a first portion which extends on the upper face and at least a second portion which extends upstream or downstream of the blocking structure along the interconnect track, the second portion not having any continuity of material with the first portion.

The presence of a blocking structure interposed between the carrier structure and the interconnect track is a simple way to achieve the discontinuity in the oxidizable layer of the interconnect track. Moreover, this solution is compatible with conventional interconnect track production methods.

According to an embodiment, the second portion extends partially between the carrier structure and the first portion; in other words, the first portion extends above the second portion.

According to an embodiment, the blocking structure has a lower face in contact with the carrier structure, the lower face having a dimension along the interconnect track (i.e. considered in a plane orthogonal to the substrate and parallel to the direction of extension of the interconnect track) that is smaller than or equal to the dimension of the upper face along the interconnect track.

According to an embodiment, the blocking structure has a trapezoidal section with a plane which is parallel to the direction of extension of the interconnect track and orthogonal to the substrate.

According to an embodiment, the blocking structure comprises (or is made of) a dielectric material or a polymer.

According to an embodiment, the blocking structure has a thickness smaller than that of the layer of conductive material. Preferably, if the method for producing the layer of conductive material includes producing a sub-layer of conductive material (or bonding layer), then the blocking structure has a thickness smaller than that of the sub-layer of conductive material.

According to an embodiment, the blocking structure is produced at a distance of greater than 200 micrometers from any component located along the interconnect track.

The component is produced using group III-V materials. For example, the integrated circuit may include an active layer, comprising the component, and produced by epitaxy of group III-V materials.

The component may be an active component, for example a high electron mobility transistor.

According to another aspect, there is proposed a method for the production of an integrated electronic device comprising at least one component on a carrier structure which comprises a semiconductor substrate, the method comprising
a step of producing, on the carrier structure, a blocking structure which has an upper face facing away from the carrier structure,
a step of producing an interconnect track which extends from the component to a lateral face of the device, comprising:
a sub-step of producing a layer of oxidizable material comprising a first portion which extends on the upper face, and at least a second portion which extends upstream or downstream of the blocking structure along the interconnect track, such that the first portion does not have any continuity of material with the second portion,
a sub-step of producing a continuous layer of conductive material on the layer of oxidizable material, in such a way as to form an interconnect track comprising the layer of oxidizable material and the layer of conductive material.

Naturally, the various features, variants and embodiments of the invention may be associated with one another in various combinations provided that they are not mutually exclusive or incompatible.

### BRIEF DESCRIPTION OF THE FIGURES

In addition, various other features of the invention will become apparent from the accompanying description that is provided with reference to the drawings, which illustrate non-limiting embodiments of the invention, and in which:

FIG. 1 is a top view of a device according to an embodiment of the invention,

FIG. 2 is a view in section of the device in FIG. 1,

FIG. 3 shows a first step in a method for the production of a device according to the invention,

FIG. 4 is a second step in a method for the production of a device according to the invention,

FIG. 5 is a third step in a method for the production of a device according to the invention,

FIG. 6 is a fourth step in a method for the production of a device according to the invention,

FIG. 7 shows a variant embodiment of the device according to the invention.

Note that, in these figures, structural and/or functional elements common to the various variants may have the same reference signs.

### DETAILED DESCRIPTION

It goes without saying that integrated circuits may be oriented in different ways, in particular depending on the way in which they are integrated into electronic devices, the latter moreover not always having a specific orientation (or reference orientation). However, for the sake of simplifying the disclosure, the reference orientation will be that which is conventionally used in reference works and in most patent documents, i.e. the carrier substrate will be considered to be at the bottom and the face of the substrate from which the various layers and components of the integrated circuit are produced, conventionally called the “front face”, will be considered to be the upper face of the substrate. Thus, relative terms such as “above”, “below”, “on”, “under”, “lateral”, “lower” and “upper” should be interpreted in accordance with this reference orientation. This orientation coincides with the orientation in FIGS. 2 to 7 of the present application.

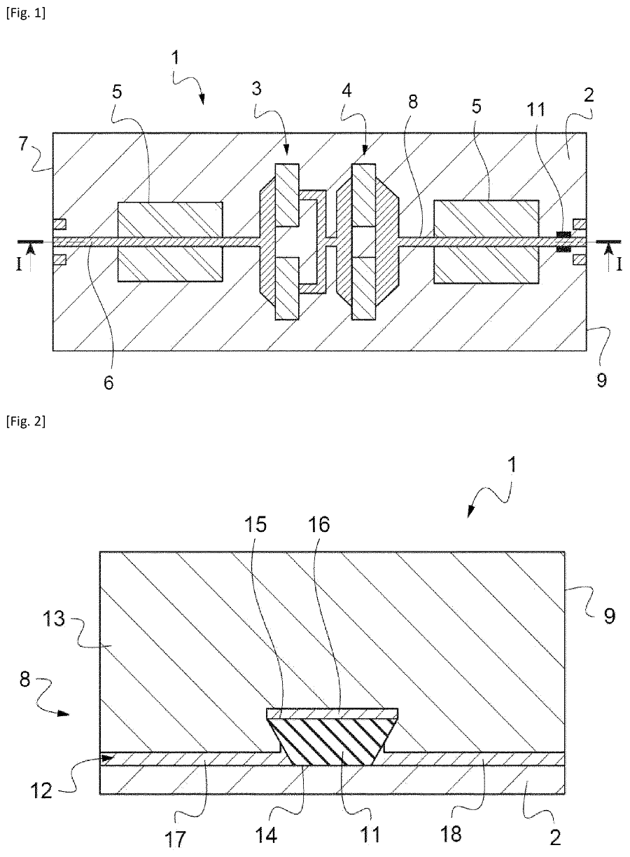

FIG. 1 is a schematic top view of an integrated electronic device 1, in this case a monolithic microwave integrated circuit (MMIC), which in this example is a high power amplifier. The integrated electronic device 1 is for example made from III-V semiconductor materials.

The integrated circuit 1 comprises a carrier structure 2 on which components and interconnect tracks are produced, and a protective layer, in this case made of dielectric material, produced on the carrier structure 2 in such a way as to encapsulate the components and the interconnect tracks. For greater clarity in the figures, the integrated circuit 1 is shown here without its protective layer.

The carrier structure 2 in this case comprises a carrier substrate, for example made of silicon carbide SiC, sapphire, silicon Si or gallium nitride GaN, on which there is a heterojunction formed by a first layer of a wide bandgap material, for example gallium nitride GaN, and a second layer of a wider bandgap material, for example aluminum-gallium nitride AlGaN. A nucleation layer, or buffer layer, comprising for example gallium nitride, is present between the carrier substrate and the first layer and makes it possible to ensure mesh adaptation for the growth of the heterojunction on the carrier substrate. For the sake of simplification, these layers will not be shown in the figures.

Components, in this case transistors, and in particular here high electron mobility transistors (HEMT), are produced on the carrier structure 2. In this case, these transistors belong to two radiofrequency power amplification stages 3, 4.

The device 1 further comprises interconnect tracks which extend from lateral faces of the device 1 and which are electrically connected to the electrodes of the transistors of the two stages 3 and 4. Within the meaning of the invention, the lateral faces of the device 1 are understood to be the faces which are orthogonal to the front face of the substrate and correspond to the cutting lines of the device 1 prior to its individualization.

In this case, a first interconnect track 6 extends from a first lateral face 7 of the device 1 toward the components in such a way as to make contact with the gate lines of the transistors of the two stages 3 and 4. The first interconnect track 6 forms, on the first lateral face 7, an input electrode for the device 1.

A second interconnect track 8 extends from a second lateral face 9 of the device 1 toward the components in such a way as to make contact with the drains of the transistors of the two stages 3 and 4. The second interconnect track 6 forms, on the second lateral face 9, an output electrode for the device 1.

A third interconnect track connects the sources of the transistors of the two stages to ground and connects the various sources, for example, by an air-bridge architecture or by a Benzocyclobutene bridge, BCB-bridge, architecture. For example, the device 1 is in this case a microstrip device and the ground plane is produced on the rear face of the substrate (or lower face, opposite the front face). The bridges (air or BCB) are connected to the ground plane by through-hole vias.

Various passive components 5 make it possible in particular to perform impedance adaptations on the interconnect tracks 6 and 8.

The interconnect tracks 6 and 8, on the lateral faces 7 and 9 respectively, are in this case exposed to the environment outside the device 1, in particular to moisture, and are therefore likely to oxidize. This risk is particularly high for the second interconnect track 8 which here forms the output terminal of the high power amplifier. The current density flowing therein is particularly high and the electromagnetic field generated promotes the migration of oxidation along the second interconnect track 8 toward the second transistor stage 4.

The device 1 comprises, near the second lateral face 9, a blocking structure 11 which makes it possible to prevent the migration of oxidation along the second interconnect track 8. Preferably, the blocking structure 11 is located at a distance from the passive components 5 of greater than 200 micrometers.

In this case, the blocking structure 11 is interposed between the carrier structure 2 and the second interconnect track 8. It extends here transversely to the second interconnect track 8, from one edge of the second interconnect track 8 to the other, and notably in this case beyond the edges of the second interconnect track 8.

This blocking structure 11 can be seen more clearly in FIG. 2, which is a sectional view of the electronic device 1 along the section line I-I in FIG. 1.

The blocking structure 11 has a first face 14, or lower face, which is in contact with the carrier structure 2, and a second face 15, or upper face, which is opposite the first face and the carrier structure 2. The dimension of the first face 14 along the interconnect track (i.e. considered parallel to the upper face of the carrier structure and in a plane parallel to the direction of extension of the interconnect track, in this case a plane parallel to the section plane I-I) is smaller than or equal to the dimension of the second face 15 along the interconnect track (i.e. considered in this same plane). The section of the carrier structure 2 (here again, in a plane parallel to the section plane I-I) is referred to as an “undercut” (according to the usual terminology).

Specifically in this case, the section of the carrier structure 2 in a plane parallel to the section plane I-I, has a trapezoidal shape. A first base of the trapezoid formed by this section belongs to the first face 14 and a second base of the trapezoid belongs to the second face 15. The length of the first base is less than the length of the second base and in this example the trapezoid is an isosceles trapezoid.

The blocking structure 11 is in this case made of a dielectric material.

The second interconnect track 8 comprises at least two layers, including a layer of oxidizable material 12 and a layer of conductive material 13. The layer of oxidizable material 12 is in this case a support layer, or bonding layer, which supports the layer of conductive material 13 and which allows better adhesion of the layer of conductive material 13 to the carrier structure 2.

In this case, the layer of oxidizable material 12 is a layer of a titanium-based alloy, here an alloy of titanium and tungsten, and is produced directly on the carrier structure 2. The layer of conductive material 13 is in this case a gold layer.

The thickness of the blocking structure 11 (distance between the first face 14 and the second face 15) is in this case greater than the thickness of the layer of oxidizable material 12 and much smaller than the thickness of the layer of conductive material 13. The blocking structure 11 has, for example, a thickness of between 60 nanometers and 80 nanometers, the layer of oxidizable material 12 has, for example, a thickness of between 20 and 30 nanometers and the layer of conductive material 13 has, for example, a thickness equal to or greater than 1 micrometer (or even equal to or greater than 5 micrometers).

The layer of oxidizable material 12 is discontinuous; the layer of oxidizable material 12 in this case comprises three portions. A first portion 16 is located on the second face 15 of the blocking structure, a second portion 17 and a third portion 18 are located on the carrier structure 2, respectively upstream and downstream along the interconnect track (relative to the direction of propagation of the signal).

As stated above, the second face 15 has a dimension along the interconnect track (i.e. here in a plane parallel to the section plane I-I) that is greater than the dimension of the first face 14 along the interconnect track. Thus, the first portion 16 extends partially above the second portion 17 and partially above the third portion 18. In other words, the first portion 16 extends at a distance from the carrier structure 2 and a part of the second portion 17 and a part of the second portion 18 are interposed (without direct contact) between the first portion 16 and the substrate. More specifically, end portions of the second and third portions 17, 18 extend between the carrier structure 2 and end portions of the first portion 16.

Given the difference in thickness between the carrier structure 11 and the layer of oxidizable material 12, the first portion 16 is not continuous with the second and third portions 17 and 18 (which are themselves not mutually continuous because they are separated by the blocking structure 11).

Conversely, the continuity of the layer of conductive material 13 is not affected by the presence of the blocking structure 11 because the thickness of the layer of conductive material 13 is greater than the thickness of the blocking structure 11.

The blocking structure 11 therefore advantageously makes it possible to break the continuity of the layer of oxidizable material 12 without breaking the continuity of the layer of conductive material 13. The electrical connection is therefore ensured up to the components. Furthermore, the blocking structure 11 does not affect the mechanical integrity of the second interconnect track since the layer of conductive material 13 is well supported by the track of oxidizable material 12 over its entire length.

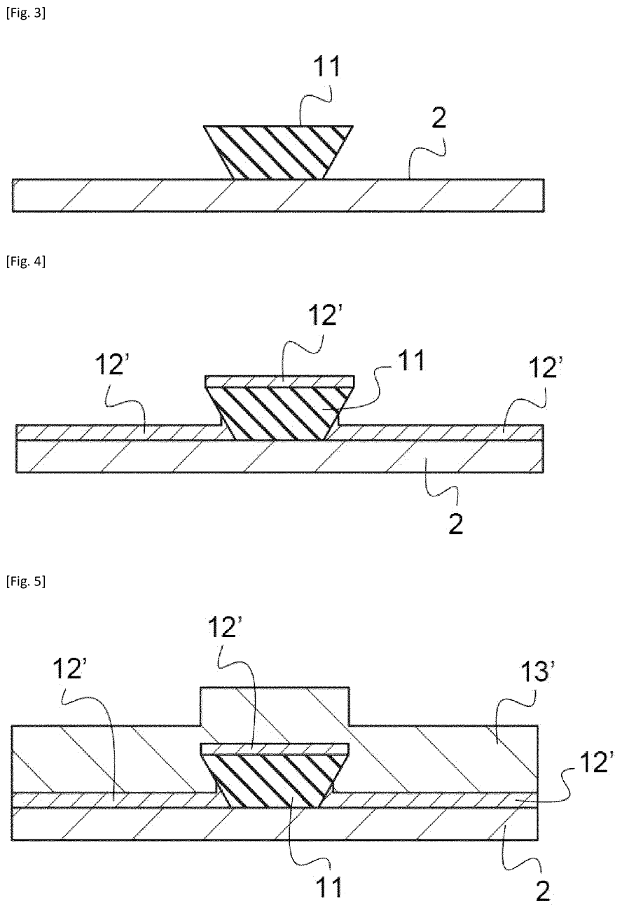

FIGS. 3 to 6 illustrate various steps of a method for the production of an integrated device according to the invention, for example the device shown in FIGS. 1 and 2.

In a first step in the production of a device according to the invention (FIG. 3), the blocking structure 11 is produced on the carrier structure 2, for example by depositing a layer of dielectric material on the carrier structure 2, in particular resin, then the blocking structure 11 is delimited in the resin layer by photolithography and dipping. The technique for producing the section referred to as “undercut”, in particular trapezoidal, of the blocking structure 11 will not be described in more detail here since it is conventional and known per se. It is notably used in methods for metal deposition by removal of layers (or “lift-off” methods as they are usually known).

A second step in the method comprises the production of the interconnect tracks.

A first sub-step (FIG. 4) for producing the interconnect tracks comprises the deposition of a layer of oxidizable material 12′ by sputtering on the carrier structure 2 and on the blocking structure 11.

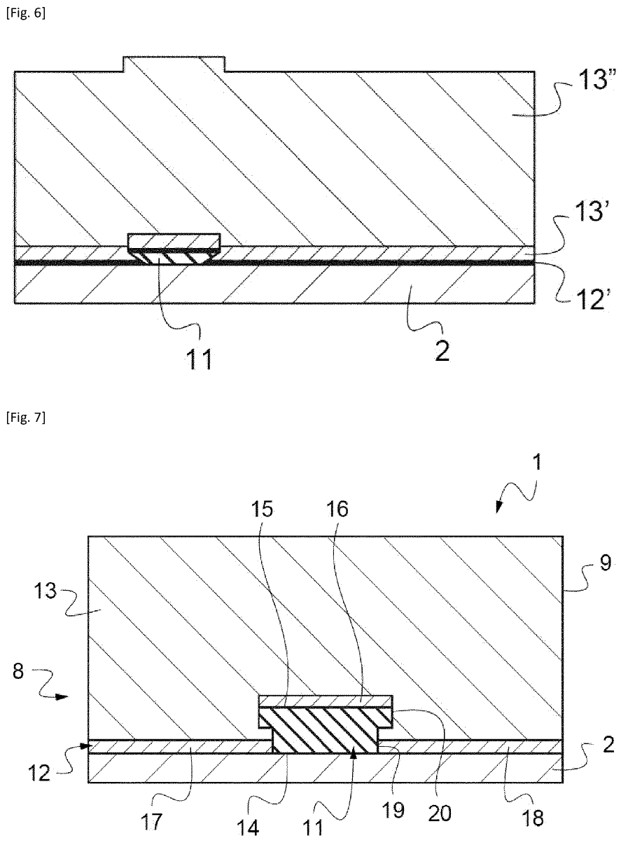

A second sub-step (FIG. 5) comprises part of the production of the layer of conductive material 13, and comprises the deposition of a first sub-layer of conductive material 13′, in this case gold, by sputtering on the layer of oxidizable material. A third sub-step (FIG. 6) comprises another part of the production of the layer of conductive material 13, and comprises electrolytic growth of a second sub-layer 13″ of the conductive material, in this case gold, on the layer of oxidizable material 12′. The production of the first sub-layer 13′ by sputtering allows homogeneous growth of the second sub-layer 13″ and thus improves the adhesion of the conductive material to the layer 12′ of oxidizable material. In this example, the first sub-layer 13′ has a thickness of 100 nanometers and the second sub-layer 13″ has a thickness of 6 micrometers.

In a fourth sub-step (not shown), the conductive tracks of the device 1, specifically the tracks 6 and 7, are delimited (or defined) in these three layers by photolithography and dipping.

The second interconnect track 8 is thus produced by conventional methods, but advantageously includes a discontinuity in the layer of oxidizable material 12 induced by the presence of the blocking structure 11.

The invention is not limited to the embodiments described above in connection with FIGS. 1 and 2. In particular, although a blocking structure of trapezoidal section has been described, other shapes are conceivable, for example a T shape, or an inverted podium shape, as shown in FIG. 7, in which the blocking structure 11 comprises a first portion 19 in the shape of a rectangular parallelepiped in contact with the substrate and a second portion in the shape of a rectangular parallelepiped 20 which is produced on the first parallelepiped portion 19 and which has a dimension along the interconnect track that is greater than the dimension of the first parallelepiped portion 19 along the interconnect track. Such a profile is for example obtained from a two-layer resin, each of the sub-layers of which has a different revelation speed (in this case, a higher revelation speed for the layer in contact with the carrier structure 2).

More generally, the invention is compatible with any blocking structure having a profile (i.e. a section in a plane parallel to the section plane I-I in FIG. 1) of undercut type.

Furthermore, the invention is particularly advantageously applicable to the field of integrated circuits comprising III-V semiconductors and to the field of monolithic microwave integrated circuits. The invention is however not limited to these applications and is compatible with any integrated circuit comprising an interconnect track comprising two layers, one of which is liable to oxidize.

A blocking structure 11 produced at a distance from the second lateral face 9 (cutting line) of the integrated device 1 has been described herein. The invention also covers embodiments in which the blocking structure 11 is flush with the second lateral face 9. Thus, the first portion 16 of the layer of oxidizable material extends as far as the second lateral face 9, and the layer of oxidizable material 12 does not have a third portion, but only a second portion which extends upstream of the blocking structure, in other words between the components and the blocking structure 11.

Lastly, the invention is not limited to embodiments which comprise only one blocking structure, and covers embodiments comprising several blocking structures, for example as many blocking structures as there are interconnect tracks likely to oxidize.

Various other modifications may be made to the invention within the scope of the appended claims.

1. An integrated electronic device comprising:
at least one component produced on a carrier structure comprising:
a semiconductor substrate; and
an interconnect track which extends on the carrier structure from the component to a lateral face of the device,
wherein the interconnect track comprising a layer of oxidizable material supporting a continuous layer of conductive material,
wherein the layer of oxidizable material is discontinuous.

2. The integrated electronic device as claimed in claim 1, comprising a blocking structure which is interposed between the carrier structure and a portion of the interconnect track, which extends transversely from one edge of the interconnect track to the other and which has an upper face facing away from the carrier structure,
wherein the layer of oxidizable material comprising a first portion which extends on the upper face and at least a second portion which extends upstream or downstream of the blocking structure along the interconnect track,
wherein the second portion not having any continuity of material with the first portion.

3. The integrated electronic device as claimed in claim 2, wherein the second portion extends partially between the carrier structure and the first portion.

4. The integrated electronic device as claimed in claim 2, wherein the blocking structure has a lower face in contact with the carrier structure, the lower face having a dimension along the interconnect track that is smaller than or equal to the dimension of the upper face along the interconnect track.

5. The electronic device as claimed in claim 2, wherein the blocking structure has a trapezoidal section with a plane (I-I) which is parallel to a direction of extension of the interconnect track and orthogonal to the substrate.

6. The integrated electronic device as claimed in claim 2, wherein the blocking structure comprises a dielectric material or a polymer.

7. The integrated electronic device as claimed in claim 2, wherein the blocking structure has a thickness smaller than that of the layer of conductive material.

8. The integrated electronic device as claimed in claim 2, wherein the blocking structure is produced at a distance of greater than 200 micrometers from any component located along the interconnect track.

9. The integrated electronic device as claimed in claim 1, wherein the component and the substrate are produced using group III-V materials.

10. The integrated electronic device as claimed in claim 1, wherein the component is a high electron mobility transistor.

11. A method for production of an integrated electronic device comprising at least one component on a carrier structure which comprises a semiconductor substrate, the method comprising:
producing, on the carrier structure, a blocking structure which has an upper face facing away from the carrier structure;
producing an interconnect track which extends from the component to a lateral face of the device;
producing a layer of oxidizable material comprising a first portion which extends on the upper face, and at least a second portion which extends upstream or downstream of the blocking structure along the interconnect track, such that the first portion does not have any continuity of material with the second portion; and
producing a continuous layer of conductive material on the layer of oxidizable material.
